(19) United States
(12) Patent Application Publication
(10) Pub. No.: US 2007/0228375 A1
(43) Pub. Date: Oct. 4, 2007

(54) Multilayer Information Recording Medium and Method for Manufacturing Same

(75) Inventors: Yuuko Tomekawa, Osaka (JP); Morio Tomiyama, Nara (JP)

Correspondence Address: HAMRE, SCHUMANN, MUELLER & LARSON P.C., P.O. BOX 2902-0902, MINNEAPOLIS, MN, 55402, US

(73) Assignee: MATSUSHITA ELECTRIC INDUSTRIAL CO., LTD., Kadoma-shi, Osaka (JP)

(21) Appl. No.: 11/576,663

(22) PCT Filed: Oct. 28, 2005
(86) PCT No.: PCT/JP05/19882

§ 371 Date: Apr. 4, 2007

(30) Foreign Application Priority Data
Oct. 29, 2004 (JP) 2004-315446

(51) Int. Cl. B05D 5/12; G11C 11/00

(52) U.S. Cl. 257/58

(57) ABSTRACT

A method for manufacturing a multilayer information recording medium including at least two information recording layers and a resin layer disposed between the information recording layers that are adjacent to each other includes a first process of filling a resin-containing coating in openings of a screen, electrically charging one of the resin-containing coating filled in the openings of the screen and a predetermined information recording layer using a charging apparatus, followed by applying the resin-containing coating filled in the openings of the screen to the predetermined information recording layer without allowing the screen and the predetermined information recording layer to contact each other, and curing a resin contained in the applied resin-containing coating so as to form the resin layer, and a second process of forming another information recording layer on the resin layer.

### TECHNICAL FIELD

The present invention relates to a multilayer information recording medium capable of recording and/or reproducing information and a method for manufacturing the same.

### BACKGROUND ART

In recent years, with an increase in the amount of information processed in information equipment, audiovisual equipment or the like, attention has been directed to an information recording medium such as an optical disk allowing easy data access and capable of storing large volumes of data and responding to the miniaturization of equipment. Also, the higher-density recording of information has been studied. As an information recording medium capable of high-density recording, an information recording medium with respect to which information is recorded and/or reproduced using a recording/reproducing apparatus provided with an optical head including a laser light source with a wavelength of about 400 nm and a focusing lens with a numerical aperture (NA) of 0.85 has been suggested (see Patent document 1, for example). In this information recording medium, it is possible to store data with a capacity of about 25 GB in a single recording layer and about 50 GB in two recording layers, for example.

Now, the structure and manufacturing method of a conventional multilayer information recording medium described in Patent document 1 will be described with reference to FIGS. 7A to 9J.

FIGS. 7A to 7F show a method for manufacturing a substrate production die (stamper) used when producing the conventional multilayer information recording medium. First, a photosensitive material such as photoresist is applied onto a glass plate 201, thereby forming a photosensitive film 202 (see FIG. 7A). Then, using a laser beam 203, an exposure is performed for transferring a pattern of pits and guide grooves to the photosensitive film 202 (see FIG. 7B). In FIG. 7B, numeral 202a denotes a portion irradiated with the laser beam 203 (an exposed portion). The photosensitive material in the exposed portion undergoes a developing process so as to be removed, so that an optical recording master 205 in which a pattern 204 of pits and guide grooves are formed on the glass plate 201 is obtained (see FIG. 7C). Next, an electrically conductive film 206 is formed on the pattern 204 by sputtering, vapor deposition or the like. This transfers the shape of the pattern 204 onto the electrically conductive film 206 (see FIG. 7C and FIG. 7D). Subsequently, a plating film 207 is formed on the electrically conductive film 206, thereby increasing the rigidity and thickness of the electrically conductive film 206 (see FIG. 7E). Thereafter, a laminate of the plating film 207 and the electrically conductive film 206 is peeled off from the optical recording master 205, thus obtaining a stamper 208 (see FIG. 7F).

FIG. 8 is a sectional view showing the conventional multilayer information recording medium. This multilayer information recording medium includes a first signal substrate 301. A first information recording layer 302 is disposed on the first signal substrate 301, and a second signal substrate 303 is disposed on the first information recording layer 302. A second information recording layer 304, a transparent layer 305 and a transparent substrate 306 are disposed in this order on the second signal substrate 303. The transparent layer 305 is provided for attaching the transparent substrate 306 to the second information recording layer 304.

The first signal substrate 301 has a surface with pits and guide grooves serving as an uneven information surface. This information surface is formed when molding the first signal substrate 301 by an injection compression molding using the stamper 208 shown in FIG. 7F. The thickness of the first signal substrate 301 is about 1.1 mm. The first information recording layer 302 and the second information recording layer 304 each include a recording film, a reflecting film, etc., and are formed by sputtering, vapor deposition or the like.

The second signal substrate 303 is formed by attaching a signal transfer substrate having an uneven surface to a photocurable resin applied by spin-coating, curing the photocurable resin and then peeling off the signal transfer substrate from the photocurable resin. The signal transfer substrate has an uneven surface similarly to the stamper 208 shown in FIG. 7F.

The transparent substrate 306 is formed of a material that is adequately transparent to recording light and/or reproducing light. The thickness of the transparent substrate 306 is about 0.1 mm. The transparent layer 305 is formed of a photocurable resin and an adhesive such as a pressure-sensitive adhesive. With respect to such a multilayer information recording medium, information is recorded/reproduced by allowing a recording/reproducing laser beam to enter from the side of the transparent substrate 306.

The following is a more detailed description of the method for manufacturing the conventional multilayer information recording medium with reference to FIGS. 9A to 9J.

First, a first information recording layer 402 is formed on an information surface of a first signal substrate 401 by sputtering, vapor deposition or the like. The first signal substrate 401 is kept fixed to a rotation table 403 by means of a suction device or the like (see FIG. 9A). Next, onto the first information recording layer 402, a coating 404 containing a photocurable resin is applied in such a manner as to form a circle with a desired radius using a dispenser (see FIG. 9B). Then, the rotation table 403 is rotated, thereby spreading the coating 404. At the time of spreading, any excess resin and air bubbles are removed by centrifugal force. The spread coating 404 can be controlled to have a desired thickness by setting the viscosity of the coating 404, the number of revolutions of the rotation table, the period for rotating the same and the atmospheric conditions (temperature, humidity etc.) as needed. After the rotation, the coating 404 is cured by light irradiation using a light irradiator 405, thus obtaining a photocurable resin layer 404′ (see FIG. 9C).

On the other hand, a signal transfer substrate 406 is fixed onto a rotation table 407. The signal transfer substrate 406 has an uneven surface similar to the stamper 208 shown in FIG. 7F (see FIG. 9D). Onto the signal transfer substrate 406, a coating 408 containing a photocurable resin is applied in such a manner as to form a circle with a desired radius using a dispenser. Then, the rotation table 407 is rotated, thereby spreading the coating 408. The thickness of the spread coating 408 can be controlled similarly to the case of the coating 404 (see FIG. 9E). After the rotation table 407 is stopped, the coating 408 is cured by light irradiation using a light irradiator 409, thus obtaining a photocurable resin layer 408′ (see FIG. 9F).

Subsequently, on the rotation table 403, a substrate 410 and a substrate 411 (see FIGS. 9C and 9F) are stacked via a coating 412 containing a photocurable resin such that the photocurable resin layers 408′ and 404′ face each other. In this state, the rotation table 403 is rotated (see FIG. 9G). By the rotation of the rotation table 403, the coating 412 is controlled (spread) to have a desired thickness. Thereafter, the coating 412 is cured by light irradiation using the light irradiator 405, thus obtaining a photocurable resin layer 412′ (see FIG. 9H). Then, the signal transfer substrate 406 is peeled off from the photocurable resin layer 408′.

It should be noted that the photocurable resin contained in the coating 404 (see FIG. 9B) is selected from resins having an excellent adhesiveness to the first information recording layer 402 and the photocurable resin layer 412′. The photocurable resin contained in the coating 408 (see FIG. 9E) is selected from resins having an excellent peelability from the signal transfer substrate 406 and an excellent adhesiveness to the photocurable resin layer 412′. The viscosities of the coatings 404, 412 and 408 are all adjusted to be about 150 cps so that a thin photocurable resin layer can be formed. Incidentally, an integral body of the photocurable resin layers 404′, 408′ and 412′ (also referred to as a resin layer) corresponds to the second signal substrate 303 in FIG. 8. For convenience of description, the above-noted integral body is illustrated to be thicker than the second signal substrate 303 in FIG. 8.

Next, a second information recording layer 413 is formed on a surface of the photocurable resin layer 408′ opposite to the side of the first signal substrate 401, namely, a second information surface by sputtering, vapor deposition or the like. On the second information recording layer 413, a coating containing a photocurable resin is applied for forming a transparent layer 415. Then, after a transparent substrate 414 is attached to the applied coating, the rotation table 403 is rotated, thereby removing air bubbles mixed into the coating and spreading the coating. Thereafter, the coating is irradiated with light having a desired wavelength through the transparent substrate 414, thus curing the photocurable resin. Thus, the coating is formed into the transparent layer 415 (see FIG. 9I).

Patent document 1: JP 2002-092969 A

### DISCLOSURE OF INVENTION

### Problem to be Solved by the Invention

However, when the resin layer, etc. are formed by spin-coating, a slight variation in film thickness in a peripheral direction and a large variation in film thickness in a radial direction are generated. In particular, in a multilayer information recording medium including a large number of information recording layers, the variations in film thickness of the signal substrate (resin layer) disposed between adjacent information recording layers add up to a large variation in thickness of the entire multilayer information recording medium.

Also, in spin-coating, the coating reaches edge portions (an outer edge portion in the example shown in FIG. 8) of the coated surface. Therefore, when curing the photocurable resin by light irradiation, the photocurable resin on the edge portions is mounded by a surface tension, so that the photocurable resin layer 404′ becomes considerably thicker on the edge portions of the coated surface than on the other portion of the coated surface (see FIG. 9J). Such a variation in thickness causes the variation in thickness of the integral body (resin layer) of the photocurable resin layers 404′, 408′ and 412′. The variation in thickness of the resin layer leads to a variation in a light spot size due to an increase in a spherical aberration at the time of recording or reproducing information using a laser beam. Furthermore, the above-noted variation in thickness adversely affects a focusing control for maintaining a focus of a light spot on an information surface or a tracking control for allowing the light spot to follow a signal train. As a result, there arises a problem that information cannot be recorded on or reproduced from the multilayer information recording medium excellently.

Further, in order to suppress the above-noted variation in thickness in spin-coating, it is necessary to produce a complicated program for controlling the rotation speed, the number of revolutions and the like of the rotation table. Also, when attempting to suppress the above-noted variation in thickness in spin-coating, there arises a problem in that a tact time (a time required to produce one product) increases.

Accordingly, the inventors of the present invention have attempted to apply a screen printing technique instead of spin-coating to the formation of the resin layer. In the following, referring to FIGS. 10A to 10D, the formation of the resin layer using the screen printing technique will be described.

As shown in FIG. 10A, first, a first signal substrate 501 whose surface is provided with a first information recording layer 502 is fixed to a table (not shown) by means of vacuum or the like. Next, a screen, for example, a screen 504 or the like is placed over the first information recording layer 502 with a predetermined clearance therebetween. The screen 504 is fixed to a screen frame 506. Then, a coating containing an ultraviolet curable resin, etc. is supplied to a portion without mesh on the screen 504, and a scraper 507 is slid as shown in FIG. 10B, thereby filling the coating into the mesh of the screen 504. Next, a squeegee 508 is slid on the screen 504 so as to apply a predetermined pressure thereto, whereby the resin-containing coating filled in the mesh of the screen 504 is pushed out of the mesh and applied onto the first information recording layer 502 (see FIGS. 10C and 10D).

However, in this method, since the screen 504 contacts the first information recording layer 502, the first information recording layer 502 may be damaged. The first information recording layer 502 is provided with fine unevenness with a depth of several tens of nanometers, and this uneven portion may be broken due to the contact of the screen 504.

Further, every time the squeegee 508 is slid on the screen 504, the screen 504 is subjected to a physical load because of its contact with the first information recording layer 502. Accordingly, the resultant abrasion or the like of the screen 504 may vary an application amount of the resin-containing coating. In addition, since the screen 504 elastically deforms repeatedly, many repetitions of printing deteriorates the peelability of the screen 504 from the first information recording layer 502, so that the application may become more uneven. Then, these problems may cause a problem that information cannot be recorded on or reproduced from the multilayer information recording medium excellently.

Thus, it is an object of the present invention to provide a multilayer information recording medium with respect to which information is reproduced and/or recorded excellently and that achieves an excellent production efficiency, and a method for manufacturing the same.

### MEANS FOR SOLVING PROBLEM

A method for manufacturing a multilayer information recording medium according to the present invention is a method for manufacturing a multilayer information recording medium including at least two information recording layers and a resin layer disposed between the information recording layers that are adjacent to each other. The method includes a first process of filling a resin-containing coating in openings of a screen, electrically charging one of the resin-containing coating filled in the openings of the screen and a predetermined information recording layer using a charging apparatus, followed by applying the resin-containing coating filled in the openings of the screen to the predetermined information recording layer without allowing the screen and the predetermined information recording layer to contact each other, and curing a resin contained in the applied resin-containing coating so as to form the resin layer, and a second process of forming another information recording layer on the resin layer.

### EFFECTS OF THE INVENTION

With the method for manufacturing a multilayer information recording medium according to the present invention, it is possible to provide a multilayer information recording medium with respect to which information is reproduced and/or recorded excellently and that achieves an excellent production efficiency, and a method for manufacturing the same.

### BRIEF DESCRIPTION OF DRAWINGS

FIG. 1 is a sectional view showing an example of a multilayer information recording medium manufactured by a method for manufacturing a multilayer information recording medium according to Embodiment 1.

FIG. 2 is a sectional view showing an example of a first information recording layer.

FIG. 3A is a sectional view for describing an example of the method for manufacturing a multilayer information recording medium according to Embodiment 1.

FIG. 3B is a sectional view for describing an example of the method for manufacturing a multilayer information recording medium according to Embodiment 1.

FIG. 3C is a sectional view for describing an example of the method for manufacturing a multilayer information recording medium according to Embodiment 1.

FIG. 3D is a sectional view for describing an example of the method for manufacturing a multilayer information recording medium according to Embodiment 1.

FIG. 3E is a sectional view for describing an example of the method for manufacturing a multilayer information recording medium according to Embodiment 1.

FIG. 4A is a sectional view for describing an example of the method for manufacturing a multilayer information recording medium according to Embodiment 1.

FIG. 4B is a sectional view for describing an example of the method for manufacturing a multilayer information recording medium according to Embodiment 1.

FIG. 4C is a sectional view for describing an example of the method for manufacturing a multilayer information recording medium according to Embodiment 1.

FIG. 4D is a sectional view for describing an example of the method for manufacturing a multilayer information recording medium according to Embodiment 1.

FIG. 5 is a sectional view for describing an example of a method for manufacturing a multilayer information recording medium according to Embodiment 2.

FIG. 6A is a sectional view for describing an example of the method for manufacturing a multilayer information recording medium according to Embodiment 2.

FIG. 6B is a sectional view for describing an example of the method for manufacturing a multilayer information recording medium according to Embodiment 2.

FIG. 6C is a sectional view for describing an example of the method for manufacturing a multilayer information recording medium according to Embodiment 2.

FIG. 6D is a sectional view for describing an example of the method for manufacturing a multilayer information recording medium according to Embodiment 2.

FIG. 7A is a sectional view for describing an example of a method for manufacturing a substrate production die used when producing a conventional multilayer information recording medium.

FIG. 7B is a sectional view for describing an example of the method for manufacturing the substrate production die used when producing the conventional multilayer information recording medium.

FIG. 7C is a sectional view for describing an example of the method for manufacturing the substrate production die used when producing the conventional multilayer information recording medium.

FIG. 7D is a sectional view for describing an example of the method for manufacturing the substrate production die used when producing the conventional multilayer information recording medium.

FIG. 7E is a sectional view for describing an example of the method for manufacturing the substrate production die used when producing the conventional multilayer information recording medium.

FIG. 7F is a sectional view for describing an example of the method for manufacturing the substrate production die used when producing the conventional multilayer information recording medium.

FIG. 8 is a sectional view for describing an example of a conventional multilayer information recording medium.

FIG. 9A is a sectional view for describing an example of a method for manufacturing a conventional multilayer information recording medium.

FIG. 9B is a sectional view for describing an example of the method for manufacturing a conventional multilayer information recording medium.

FIG. 9C is a sectional view for describing an example of the method for manufacturing a conventional multilayer information recording medium.

FIG. 9D is a sectional view for describing an example of the method for manufacturing a conventional multilayer information recording medium.

FIG. 9E is a sectional view for describing an example of the method for manufacturing a conventional multilayer information recording medium.

FIG. 9F is a sectional view for describing an example of the method for manufacturing a conventional multilayer information recording medium.

FIG. 9G is a sectional view for describing an example of the method for manufacturing a conventional multilayer information recording medium.

FIG. 9H is a sectional view for describing an example of the method for manufacturing a conventional multilayer information recording medium.

FIG. 9I is a sectional view for describing an example of the method for manufacturing a conventional multilayer information recording medium.

FIG. 9J is a partially enlarged view of FIG. 9C.

FIG. 10A is a sectional view for describing an example of a method for manufacturing a multilayer information recording medium.

FIG. 10B is a sectional view for describing an example of the method for manufacturing a multilayer information recording medium.

FIG. 10C is a sectional view for describing an example of the method for manufacturing a multilayer information recording medium.

FIG. 10D is a sectional view for describing an example of the method for manufacturing a multilayer information recording medium.

### EXPLANATION OF LETTERS OR NUMERALS

601 First signal substrate
601a Outer edge portion
601b Inner edge portion
602 First information recording layer
603 Resin layer
604 Second information recording layer
605 Resin layer
606 Third information recording layer
607 Resin layer
608 Fourth information recording layer
609 Transparent layer
610 Center hole
503 Reflecting film
504 First dielectric film
505 Recording film
506 Second dielectric film
618 Corona charger
619 Electric charge supplying device
613 Table
104 Screen
105 Resin-containing coating
105′ Resin-containing coating layer
106 Screen frame
107 Scraper
108 Squeegee
701 Decompression chamber
702 Signal transfer substrate
703 Pressure-reducing pump
704 Pressing plate
705 Ultraviolet irradiating device
706 Center boss
901 Disk charging portion
902 Resin printing portion
903 Attaching portion
904 Peeling portion
905 First signal substrate whose one principal surface is provided with first information recording layer
906 Table
907 Corona charger
908 UV lamp
909 Signal transfer substrate
910 Substrate to which information surface is transferred using signal transfer substrate (Substrate)
911 Pressure-reducing pump
912 Pressure detection device
1001 First signal substrate
1002 Electrically-charged first information recording layer
1003 Table
1004 Screen
1005 Resin-containing coating
1005′ Resin-containing coating layer
1006 Screen frame
1007 Scraper
1008 Squeegee

### DESCRIPTION OF THE INVENTION

In an example of a method for manufacturing a multilayer information recording medium according to the present invention, a corona charger is used as the charging apparatus, for example.

In an example of the method for manufacturing a multilayer information recording medium according to the present invention, when applying the resin-containing coating filled in the openings of the screen to the predetermined information recording layer, a sliding member is slid on the screen so as to press the resin-containing coating filled in the openings of the screen toward the predetermined information recording layer. At this time, it is preferable to make the screen and the predetermined information recording layer face each other such that a minimum distance between the screen and the predetermined information recording layer is equal to or smaller than 2.5 mm.

In an example of the method for manufacturing a multilayer information recording medium according to the present invention, it is preferable that the resin-containing coating filled in the openings of the screen is applied to the predetermined information recording layer at a pressure lower than atmospheric pressure.

In an example of the method for manufacturing a multilayer information recording medium according to the present invention, it is preferable that the resin-containing coating contains, for example, a photocurable resin and that the photocurable resin contains, for example, an ultraviolet curable resin. This is because the ultraviolet curable resin responds with a high sensitivity only to light at wavelengths in an ultraviolet range and cures itself.

Also, it is preferable that the resin-containing coating contains a surfactant or a defoaming agent. When the resin-containing coating contains a surfactant, the leveling of the applied resin-containing coating is carried out excellently. When the resin-containing coating contains a defoaming agent, bubbles in the resin-containing coating can be removed.

In an example of the method for manufacturing a multilayer information recording medium according to the present invention, in the first process, a resin-containing coating layer that is formed by applying the resin-containing coating and is located on the predetermined information recording layer and a signal transfer substrate having an uneven surface as an information surface are attached to each other such that the information surface faces the resin-containing coating, the resin contained in the resin-containing coating layer is cured so as to form the resin-containing coating layer into the resin layer, and the signal transfer substrate is peeled off from the resin layer. It is preferable that the resin-containing coating layer and the signal transfer substrate are attached to each other at a pressure lower than atmospheric pressure. Since the resin-containing coating layer and the signal transfer substrate are attached to each other at a pressure lower than atmospheric pressure, the presence of air bubbles in the resin layer is suppressed, thus suppressing the presence of air bubbles in an optical path. Accordingly, in the multilayer information recording medium, the variation in light spot size due to an increase in a spherical aberration can be suppressed, and a focusing control and a tracking control can be performed stably.

In an example of the method for manufacturing a multilayer information recording medium according to the present invention, the first process is carried out at a pressure lower than atmospheric pressure. In this way, by carrying out all of the electrical charging, the application of the resin-containing coating, the attachment of the signal transfer substrate and the resin-containing coating layer to each other, the curing and the peeling of the signal transfer substrate in the decompressed atmosphere, it is possible to reduce contamination of the information recording medium, bubbles in the resin layer and the presence of air bubbles in the resin-containing coating during application.

It is preferable that the above-described signal transfer substrate contains a polyolefin resin. The reason is that, since polyolefin is a material with an excellent peelability from the ultraviolet curable resin, it is possible to peel off the signal transfer substrate from the resin layer with a small force and prevent the resin from adhering to the signal transfer substrate.

In an example of the method for manufacturing a multilayer information recording medium according to the present invention, it is preferable that the resin-containing coating layer and the signal transfer substrate are attached to each other after a predetermined period has elapsed since the resin-containing coating is applied. This is because, within the above-mentioned predetermined period, the surface unevenness of the resin-containing coating applied through the openings of the screen can be smoothed out naturally, and the resin-containing coating layer and the signal transfer substrate can be attached to each other excellently.

In a multilayer information recording medium manufactured by the method for manufacturing a multilayer recording medium according to the present invention, the variation in thickness of the resin layer is small. Accordingly, the variation in an optical path length from the surface of the multilayer information recording medium on a light incident side to each information surface also is small. Also, in the information recording medium according to an embodiment of the present invention, the variation in light spot size due to an increase in a spherical aberration can be suppressed, and a focusing control and a tracking control can be performed stably. Therefore, in the information recording medium according to the present invention, information can be recorded or reproduced excellently.

The following is a description of embodiments of the present invention, with reference to the accompanying drawings. Although a disc-shaped information recording medium will be described below as an example, a multilayer information recording medium in the present invention is not limited to this but may be a memory card, for example.

### Embodiment 1

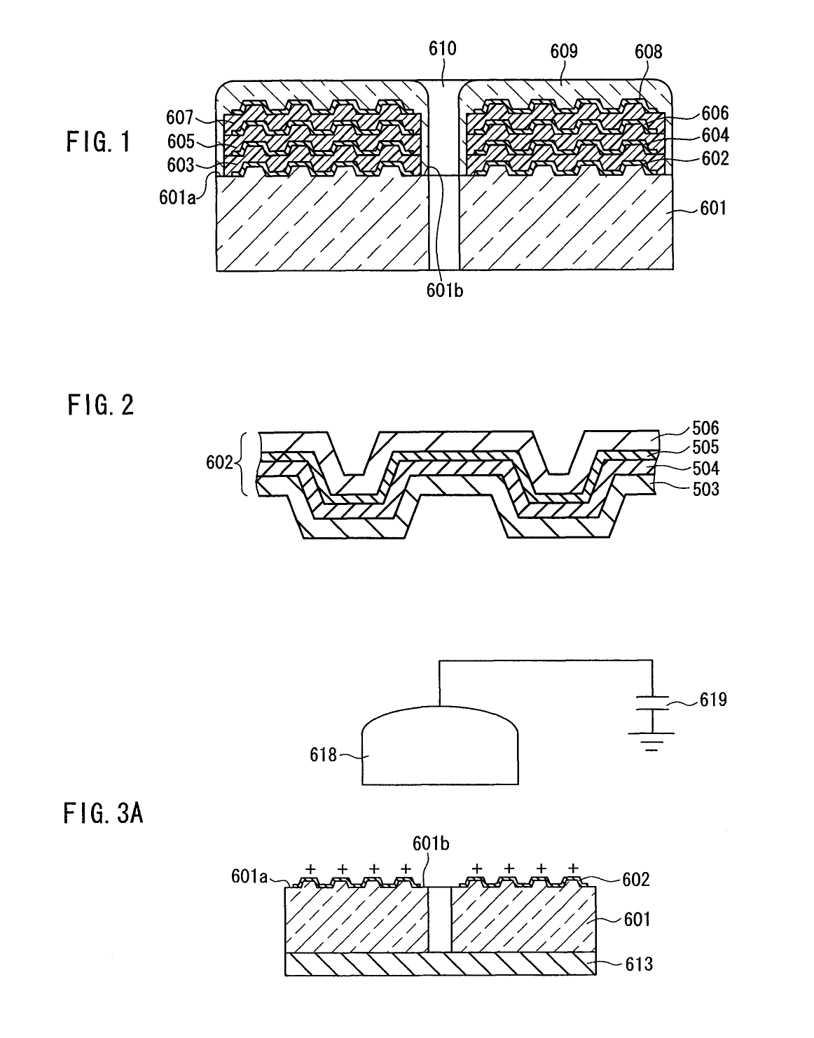

FIG. 1 is a sectional view showing a multilayer information recording medium in the present embodiment. As shown in FIG. 1, the multilayer information recording medium includes a first signal substrate 601 and a first information recording layer 602 disposed on an information surface of the first signal substrate 601. The first signal substrate 601 has a surface with pits and guide grooves serving as an uneven information surface. Also, the multilayer information recording medium includes a second signal substrate 603 disposed on the first information recording layer 602. The second signal substrate 603 has a surface with pits and guide grooves serving as an uneven information surface (a surface on a side opposite to the first signal substrate 601). The multilayer information recording medium includes a second information recording layer 604 disposed on this information surface. The multilayer information recording medium includes a third signal substrate 605 disposed on the second information recording layer 604. The third signal substrate 605 has a surface with pits and guide grooves serving as an uneven information surface (a surface on a side opposite to the second signal substrate 603). The multilayer information recording medium includes a third information recording layer 606 disposed on this information surface. The multilayer information recording medium includes a fourth signal substrate 607 disposed on the third information recording layer 606. The fourth signal substrate 607 has a surface with pits and guide grooves serving as an uneven information surface (a surface on a side opposite to the third signal substrate 605). The multilayer information recording medium includes a fourth information recording layer 608 disposed on this information surface and a transparent layer 609 disposed on the fourth information recording layer 608.

Incidentally, in the present application, the second to fourth signal substrates 603, 605 and 607 also are referred to as resin layers 603, 605 and 607.

The first signal substrate 601 is formed as a disc having an outer diameter φ of 120 mm and a thickness of 1.0 to 1.1 mm in order to suppress the warping of the information recording medium, increase the rigidity thereof and secure the compatibility with other optical disks (such as CDs and DVDs). The material for the first signal substrate 601 can be, for example, polycarbonate or acrylic resin. In the multilayer information recording medium shown in FIG. 1, polycarbonate is used as the material for the first signal substrate 601.

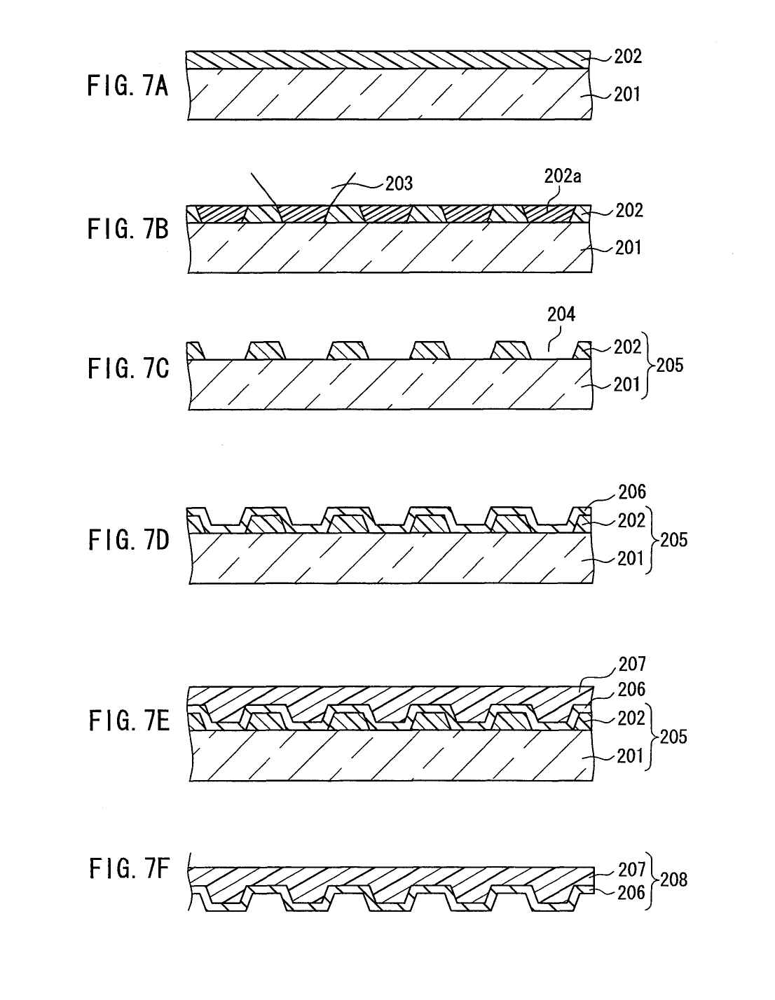

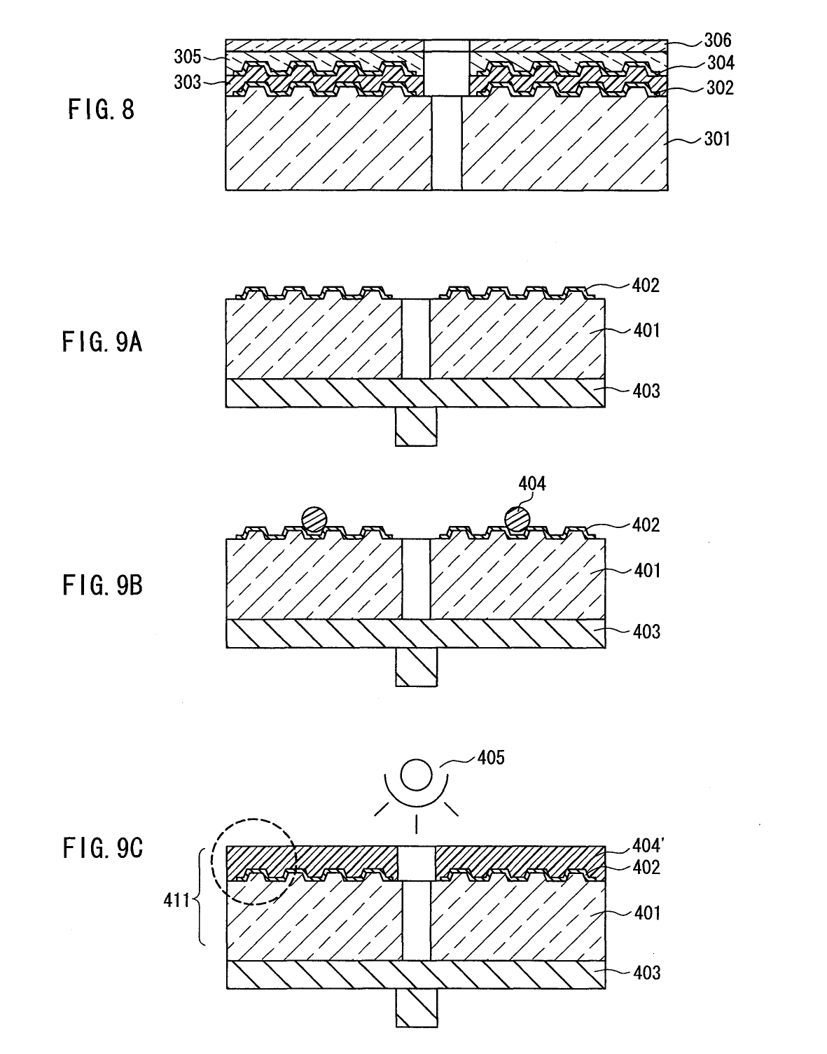

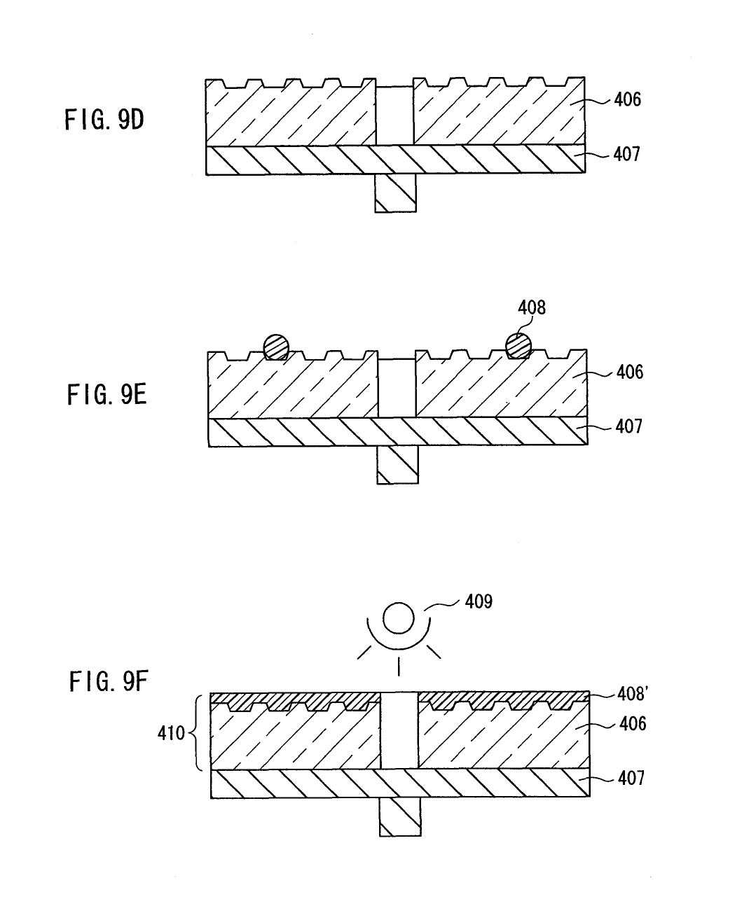

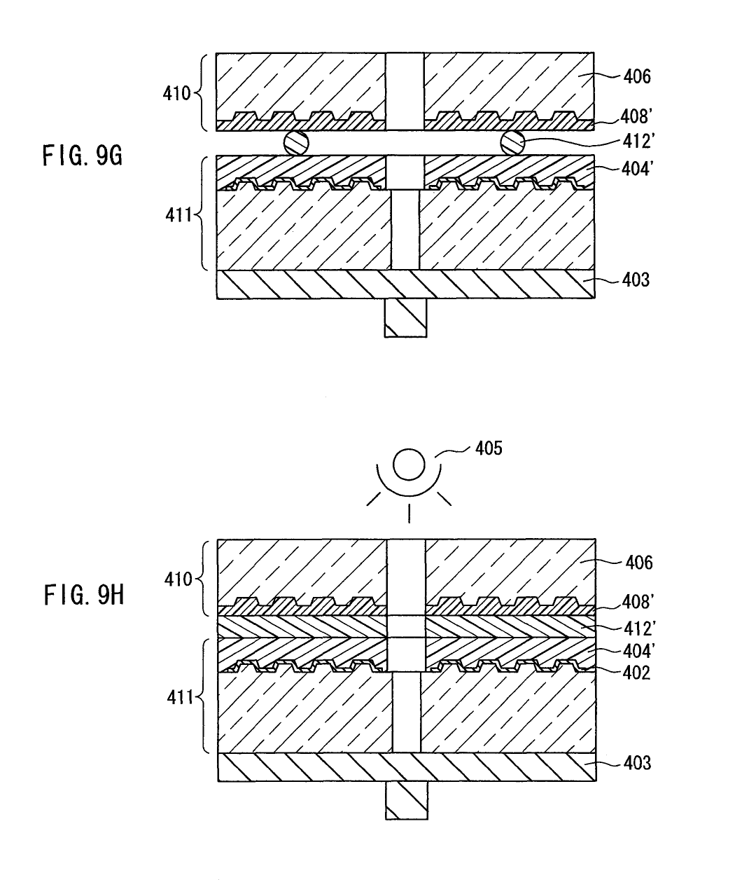

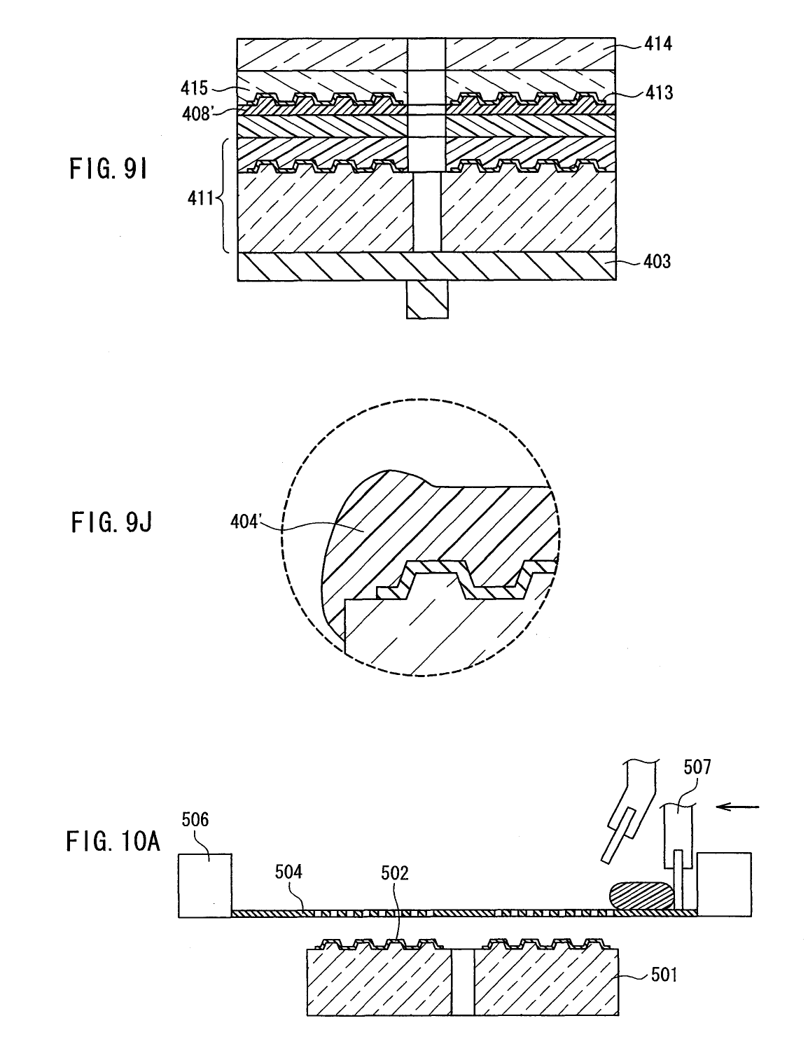

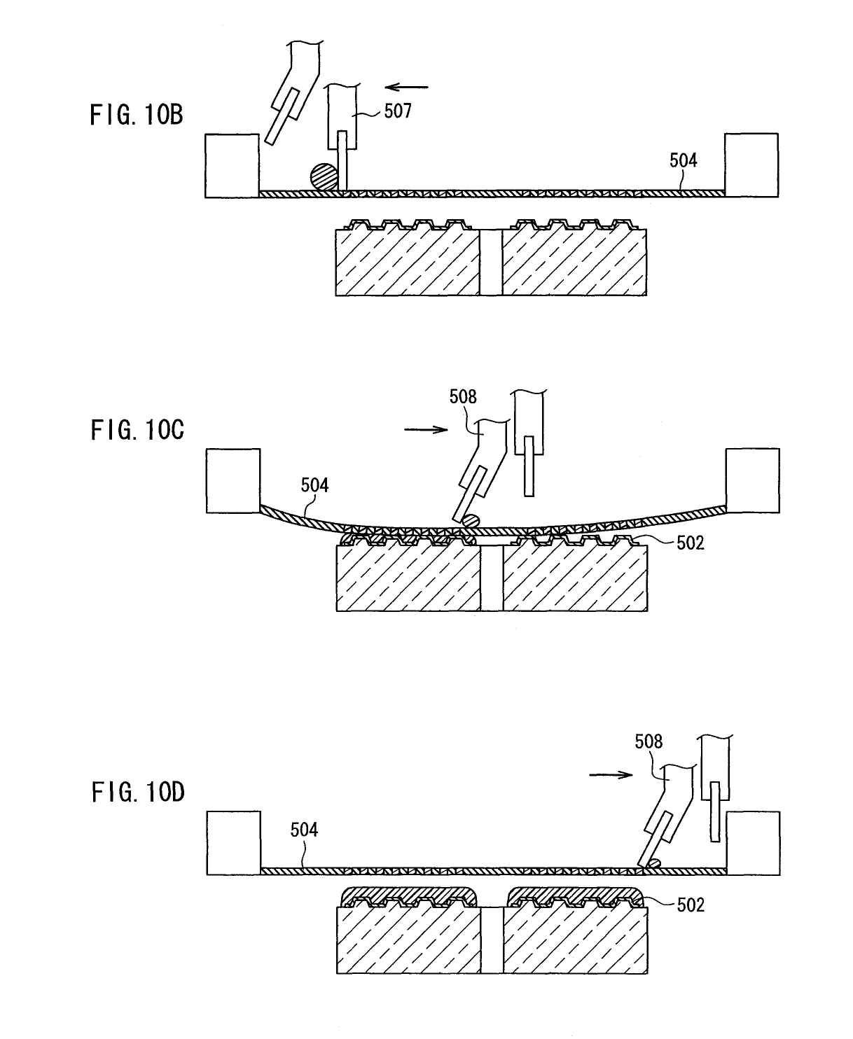

The uneven information surface is formed when molding the first signal substrate 601 using the stamper 208 shown in FIG. 7F. The first signal substrate 601 can be formed by an injection compression molding or the like, for example. The first signal substrate 601 has a center hole 610 with a diameter φ of 15 mm at its center. Through this center hole 610, the multilayer information recording medium is held rotatably at a predetermined position of a player when information is recorded/reproduced by the player.

In the case where the resin layers (second to fourth signal substrates) 603, 605 and 607 and the transparent layer 609 that are formed on the first signal substrate 601 contain a photocurable resin, a photocuring shrinkage occurs when forming these layers. This photocuring shrinkage causes the first signal substrate 601 to warp. Accordingly, it is preferable that the first signal substrate 601 is preformed to warp in the opposite direction so that no warp should occur in the multilayer information recording medium after forming the resin layers 603, 605 and 607 and the transparent layer 609.

In the case where the multilayer information recording medium according to the present embodiment is a read-only multilayer information recording medium (ROM), the first information recording layer 602 may be formed only of a reflecting film made of a metal such as Al, Ag, Au, a semiconductor such as Si or a dielectric such as SiO₂, for example. This reflecting film can be formed by sputtering, vapor deposition or the like, for example.

The structure of the first information recording layer 602 in the case where the multilayer information recording medium according to the present embodiment is a write once-type multilayer information recording medium will be described with reference to FIG. 2.

The first information recording layer 602 includes an AlCr reflecting film 503, a ZnS first dielectric film 504, a TeOPd recording film 505 and a ZnS second dielectric film 506 in this order from the side of the first signal substrate 601 (see FIG. 1), for example. All of these layers are formed by, for example, sputtering or vapor deposition. As the material for the reflecting film 503, a material containing a metal such as Ag or Au as a principal component may be used instead of AlCr, similarly to the read-only multilayer information recording medium. Further, the first information recording layer 602 may include a dye film or the like as a recording film. According to optical characteristics required at the time of recording/reproducing, the thickness of the reflecting film 503, the recording film 505, the first dielectric film 504 or the second dielectric film 506 is adjusted suitably. There are some cases where the reflecting film 503 is spaced from the first information recording layer 602.

The second information recording layer 604, the third information recording layer 606 and the fourth information recording layer 608 also have a structure similar to the first information recording layer 602.

The resin layer (second signal substrate) 603 is substantially transparent to recording/reproducing light. It is preferable that the resin layer 603 is formed of an ultraviolet curable resin containing an acrylic resin as a principal component, for example. This is because the ultraviolet curable resin responds with a high sensitivity only to light at wavelengths in an ultraviolet range and cures itself. Therefore, even if a resin-containing coating applied to the first information recording layer 602 is heated using electromagnetic waves in a wavelength range longer than the ultraviolet light, the ultraviolet curable resin contained in the resin-containing coating is not cured by these electromagnetic waves. Thus, by heating the resin-containing coating using the electromagnetic waves in the wavelength range longer than the ultraviolet light, it becomes possible to smooth out the surface of the applied resin-containing coating without curing the ultraviolet curable resin.

The resin layer 603 is produced as follows, for example. A resin-containing coating that contains an ultraviolet curable resin (sometimes simply referred to as a “coating”) is applied onto the first signal substrate 601 through openings in a screen for forming the resin layer 603. With an information surface of a signal transfer substrate pressed against the applied coating, the ultraviolet curable resin contained in the coating is cured using ultraviolet light. Then, the signal transfer substrate is peeled off from the cured ultraviolet curable resin. It is noted that the resin-containing coating is applied onto the first signal substrate 601 except for an outer edge portion 601a and an inner edge portion 601b of the first signal substrate 601. Since the first information recording layer 602 is formed on the first signal substrate 601, the coating is applied onto the first signal substrate 601 via the first information recording layer 602.

The resin layers (third and fourth signal substrates) 605 and 607 also are formed of a material similar to the resin layer (second signal substrate) 603 by a method similar thereto into a shape similar thereto.

The resin-containing coating may contain not only the resin such as the ultraviolet curable resin but also a solvent for adjusting viscosity, a cure initiator, etc.

The transparent layer 609 is substantially transparent to recording/reproducing light. It is preferable that the transparent layer 609 is formed of an ultraviolet curable resin containing an acrylic resin as a principal component, for example. The transparent layer 609 also can be formed by a method similar to the resin layer. The transparent layer 609 is formed so as to cover the first to fourth information recording layers 602, 604, 606 and 608 and the resin layers 603, 605 and 607 and, for example, partially join with the outer edge portion 601a and the inner edge portion 601b of the first signal substrate 601.

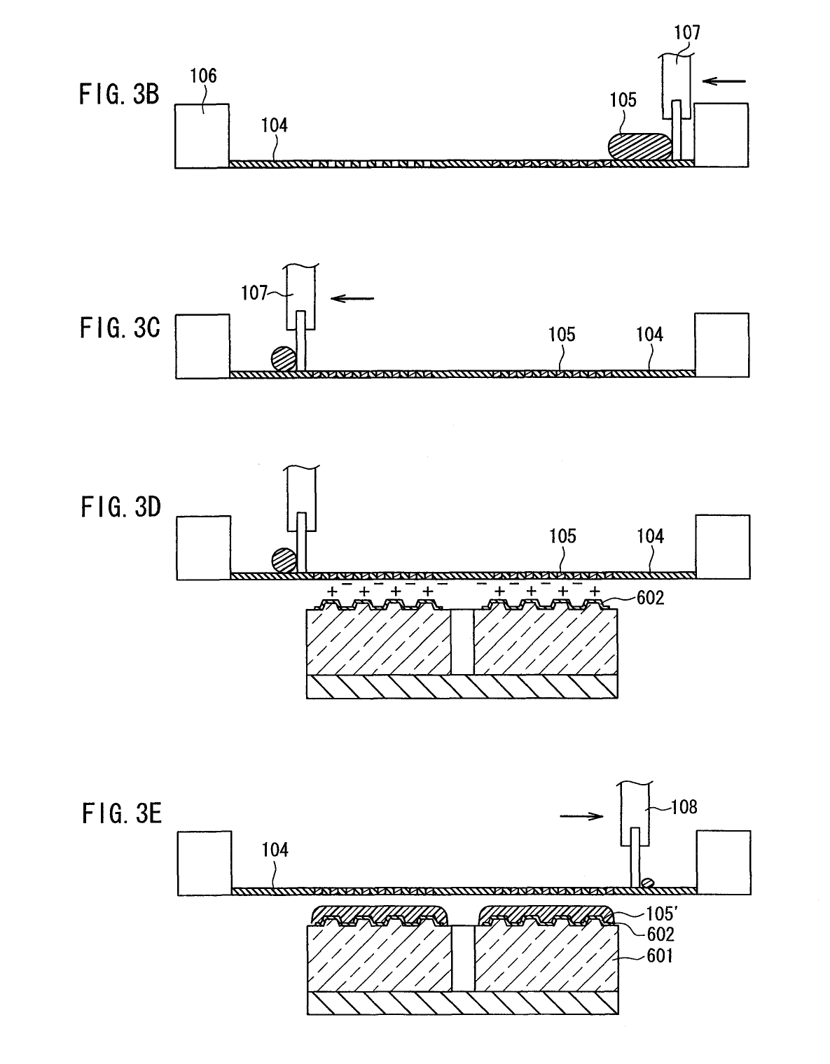

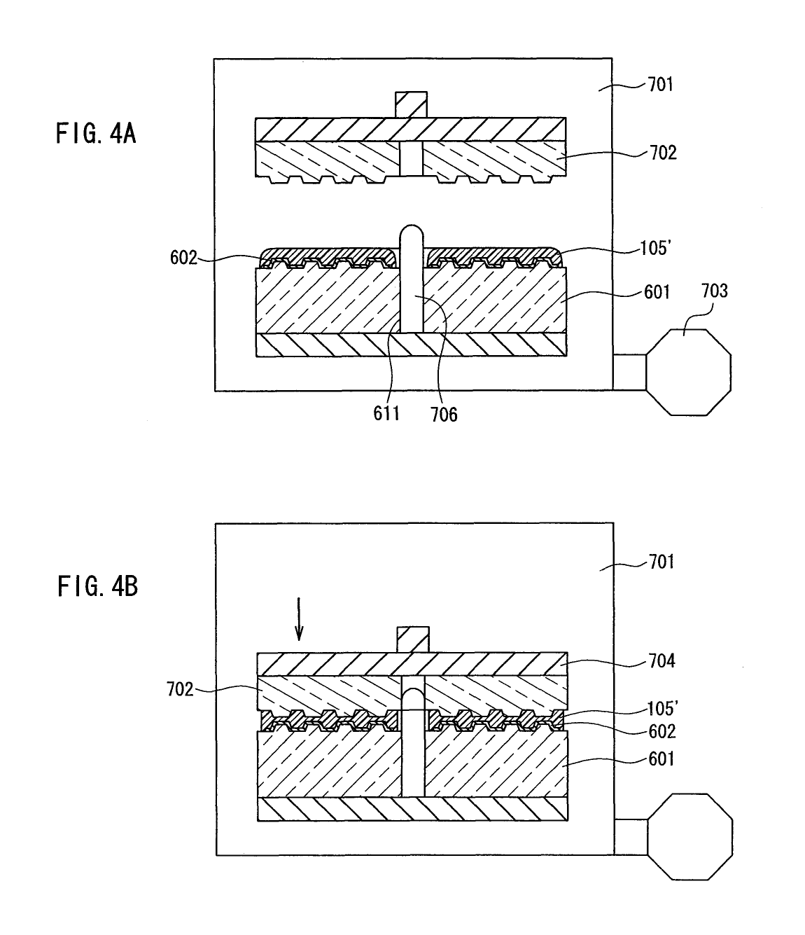

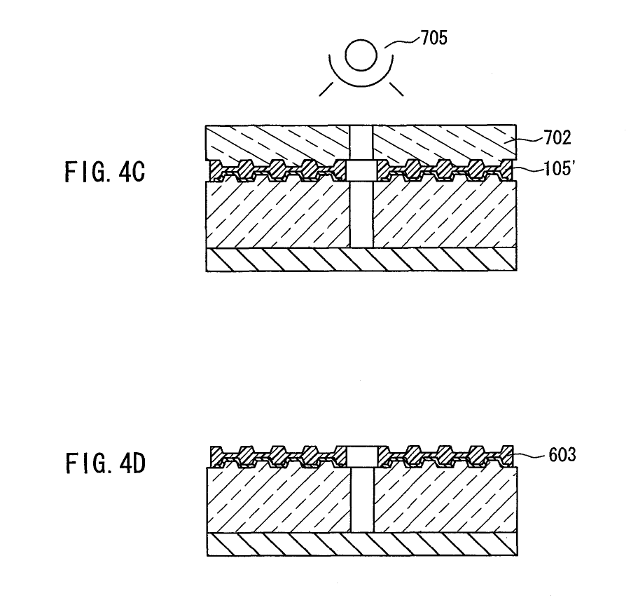

Next, an example of a method for manufacturing the multilayer information recording medium according to the present embodiment will be described referring to FIGS. 3A to 4D.

FIGS. 3A to 4D are sectional views for describing an example of the method for manufacturing the multilayer information recording medium according to the present embodiment.

In the method for manufacturing the multilayer information recording medium according to the present embodiment, first, the first information recording layer 602 including the recording film, the reflecting film, etc. is formed on the information surface of the first signal substrate 601 as shown in FIG. 3A. The recording film, the reflecting film, etc. each are formed by sputtering, vapor deposition or the like. The first signal substrate 601 is fixed to a table 613 by means of vacuum or the like, as necessary.

Next, a charging apparatus is prepared, and the first information recording layer 602 is charged electrically using the charging apparatus. The charging apparatus is constituted by a corona charger 618 and an electric charge supplying device 619. The corona charger 618 utilizes a corona discharge, which is one form of a gas discharge, and electrically charges an insulating surface. The charging system of the corona charger 618 used in the present embodiment is a scorotron system, and the corona charger 618 includes a discharge wire and a grid (not shown). The electric charge supplying device 619 is provided for applying a predetermined voltage to the discharge wire and the grid, and applies a voltage of 3 to 12 kV to the discharge wire. In the example illustrated in FIG. 3A, the first information recording layer 602 is charged positively.

A charging amount depends on the distance between the corona charger 618 and the first information recording layer 602 and a voltage applied to the discharge wire, etc. Although the charging amount may be adjusted suitably according to the material contained in the resin-containing coating and the application amount thereof, it is preferable that the first information recording layer 602 is charged electrically so that its surface has an electric charge density of at least 10⁻⁴ C/m², in order to promote the attraction of the resin-containing coating toward the side of the first information recording layer 602.

Now, the production of a screen 104 will be described. First, a screen material is stretched on a screen frame 106 and coated with a photosensitive emulsion. Thereafter, parts other than predetermined positions (positions at which a plurality of openings are to be formed) in the coated screen material are covered with a light-shielding mask. The screen material is irradiated with ultraviolet light for a predetermined period using exposure equipment. Then, the photosensitive emulsion that has been exposed to light by the ultraviolet irradiation is washed with water by a water jet or the like and then developed, thus obtaining the screen 104 (see FIG. 3B).

The material for the screen frame 106 can be, for example, wood, aluminum, stainless steel, plastics or the like. However, aluminum is particularly preferable because of its light weight and high rigidity. The screen material can be, for example, silk, stainless steel, Nylon®, a resin material such as polyethylene terephthalate or the like. However, polyethylene terephthalate is particularly preferable because it is easy to charge by electrostatic induction. The photosensitive emulsion can be an agent obtained by mixing and dissolving a diazonium salt or a dichromate into PVA or vinyl acetate emulsion, for example.

For regulating the application amount appropriately and allowing a uniform application, it is preferable that the mesh number (the number of threads per inch) at a predetermined position in the screen material is 150 to 600. If the mesh number falls within this range, the resin-containing coating can be applied so as to have a desired thickness without causing poor passage or uneven application of the resin-containing coating. Incidentally, the openings in the screen are not limited to the mesh.

It is preferable that a resin-containing coating 105 has a viscosity of 30 to 4000 mPa·s (30 to 4000 cps). When the viscosity of the resin-containing coating 105 is too low, the applied resin-containing coating 105 may flow to end faces of the first signal substrate 601. When the viscosity of the resin-containing coating 105 is too high, it becomes difficult for the resin-containing coating 105 to pass through the openings of the screen 104, so that it also becomes difficult to apply the coating. From the above, it is preferable that the resin-containing coating 105 has a viscosity of 30 to 4000 mPa·s (30 to 4000 cps). Considering a decrease in the viscosity of the resin-containing coating 105 due to the variation in temperature or humidity of the atmosphere, it is preferable that the resin-containing coating 105 has a viscosity of 100 to 4000 mPa·s (100 to 4000 cps).

In the present application, the viscosity of the resin-containing coating 105 is a value measured using a rotating viscometer. The method of measuring the viscosity using a rotating viscometer utilizes the fact that a torque of a rotating body is proportional to the viscosity. The rotating body can be, for example, a cylindrical rotor, a blade or the like. The torque refers to a force necessary to keep the rotating body put in a sample (the resin-containing coating) rotating at a constant speed by a motor or the like connected via a rod-like shaft.

By selecting a region where the openings are formed in the screen 104, it is possible to restrict the application range of the resin-containing coating 105. For example, the present embodiment uses the screen 104 with a region that extends outside the inner diameter of the first signal substrate 601 (e.g., at a distance equal to or greater than 10.5 mm from the center) and inside the outer diameter thereof (e.g., at a distance equal to or smaller than 59.75 mm from the center) to which the resin-containing coating 105 can be applied. The use of such a screen 104 makes it possible to apply the resin-containing coating 105 onto the first signal substrate 601 except for the edge portions 601a and 601b (see FIG. 3A), namely, onto the region that is inside a circle with a diameter φ of 119.5 mm and outside a circle with a diameter φ of 21 mm.

In the above example, the outer edge portion 601a of the first signal substrate 601 is the region from the outer perimeter extending inward by a distance smaller than 0.25 mm, and the inner edge portion 601b of the first signal substrate 601 is the region from the inner perimeter extending outward by a distance smaller than 3 mm. However, the edge portions are not limited to the above in the method for manufacturing a multilayer information recording medium in the present embodiment.

In the case where the multilayer information recording medium according to the present embodiment has, for example, an outer peripheral information signal region, it is preferable that the outer edge portion 601a of the first signal substrate 601 is located outside the outer peripheral information signal region. For example, in a Blu-ray Disc, the region located at a distance greater than 58.5 mm from the center is the outer edge portion 601a. It should be noted that information about the outer periphery of the multilayer information recording medium is recorded in the outer peripheral information signal region.

In the case where the multilayer information recording medium according to the present embodiment has a clamping region to be fixed to a spindle by a clamping mechanism, the clamping region is provided in a region located at a distance of 11.5 to 16.5 mm from the center, for example. In this case, the inner edge portion 601b of the first signal substrate 601 is the region that is located inside the clamping region or the region that is a combination of the clamping region and the region inside the clamping region in the first signal substrate 601. This is because it is not preferable for the resin layer to be present partially on the clamping region.

The multilayer information recording medium according to the present embodiment may have, for example, an inner peripheral information signal region in which information about the inner periphery of the multilayer information recording medium is recorded. In this case, the inner edge portion 601b of the first signal substrate 601 may be located inside the inner peripheral information signal region in the first signal substrate 601, for example. In a Blu-ray disc, for example, the region located at a distance smaller than 21.0 mm from the center is the inner edge portion 601b.

As described above, in the method for manufacturing a multilayer information recording medium according to the present embodiment, the resin-containing coating is applied onto the first signal substrate except for the edge portions of this substrate through the openings of the screen. Therefore, in the resin layer, it is possible to suppress the mounding or spew of the resin on the edge portions of the first signal substrate. This suppresses the variation in thickness of the outer edge portion and the inner edge portion and the variation in optical path therein. Consequently, it is possible to suppress the variation in light spot size due to an increase in spherical aberration, thus providing a multilayer information recording medium that allows a focusing control and a tracking control to be performed stably. Furthermore, the method for manufacturing a multilayer information recording medium according to the present embodiment can provide a multilayer information recording medium having a high dimensional accuracy and an excellent external appearance.

Further, in the method for manufacturing a multilayer information recording medium according to the present embodiment, since there is no need for a complicated program for controlling the rotation speed, the number of revolutions and the like of the rotation table, the tact time (a time required to produce one product) can be made shorter than in the case of forming the resin layer by spin-coating, so that an excellent production efficiency is achieved. In addition, in the method for manufacturing a multilayer information recording medium according to the present embodiment, since the resin-containing coating is applied by screen printing, the resin layer with a more uniform thickness can be formed more speedily than in the case of applying the resin-containing coating by spin-coating.

Next, as shown in FIG. 3C, a scraper 107 is slid on the screen 104, thereby filling the resin-containing coating 105 containing the ultraviolet curable resin into the openings of the screen 104.

Then, as shown in FIG. 3D, the screen 104 whose openings are filled with the resin-containing coating is brought closer to the electrically-charged first information recording layer 602. At this time, since the first information recording layer 602 is charged positively, the surface of the resin-containing coating that is brought closer thereto is charged negatively by electrostatic induction, so that an attractive force is generated between the resin-containing coating and the first information recording layer 602. Thus, by sliding a sliding member such as a squeegee 108, for example, on the surface of the screen 104 opposite to the side of the first information recording layer 602 so as to apply a predetermined pressure to the resin-containing coating, it is possible to make the resin-containing coating adhere to the first information recording layer 602 uniformly even if the first information recording layer 602 and the screen 104 are not in contact with each other (see FIG. 3E).

The scraper 107 and the squeegee 108 mentioned above are formed of a material such as a silicone rubber, polyurethane or stainless steel. The thickness (amount) of the resin-containing coating 105 to be applied to the first signal substrate 601 varies depending on the angle of the squeegee 108 with respect to the screen 104, the pressure applied by the squeegee 108 and the moving speed of the squeegee 108. Therefore, it is desired that the above-mentioned angle, pressure and speed be kept constant.

In the present embodiment, information is recorded on or reproduced from the multilayer information recording medium using a recording/reproducing head including an objective lens whose numerical aperture is 0.85 and a 405 nm wavelength laser light source. Thus, the resin-containing coating 105 was applied so that the average thickness of the resin layer is 10 to 25 μm, for example.

The resin-containing coating applied onto the first signal substrate 601 has an application pattern (a screen pattern) immediately after the application because it has been applied through the openings of the screen 104. Thus, it is preferable to allow the substrate to stand for a predetermined period after applying the resin-containing coating so as to reduce the unevenness from the application pattern on the surface of the resin-containing coating 105, thereby leveling the resin-containing coating (smoothing out the surface unevenness). At the time of leveling, air bubbles that have entered the resin-containing coating can be removed.

Although the above-noted predetermined period varies depending on the viscosity of the resin-containing coating, it preferably is about 4 to 120 seconds in general. For example, when the viscosity of the resin-containing coating at the time of application is 30 to 4000 mPa·s, the leveling begins immediately after the application, and it takes about 4 seconds to smooth out the surface and remove the air bubbles if the resin-containing coating has a relatively low viscosity and a low thixotropy. On the other hand, if the resin-containing coating has a relatively high viscosity and a high thixotropy, since it flows slowly, the leveling does not occur easily, so that it takes about 120 seconds to smooth out the surface and remove the air bubbles. It should be noted that the degree of “smoothness” is sufficient as long as the first signal substrate 601 and a signal transfer substrate 702 (see FIG. 4A) can be attached to each other excellently.

Heating the applied resin-containing coating is more preferable because the leveling is accelerated. As a heating device, a far infrared heater is preferably used so as not to cure the ultraviolet curable resin contained in the resin-containing coating, for example. In the case where the resin-containing coating contains the ultraviolet curable resin, it preferably is heated such that its surface temperature falls within the range of 40° C. to 120° C. Within this temperature range, it is possible to remove the unevenness substantially while suppressing the deterioration of the ultraviolet curable resin, allowing an optimal leveling. Considering the deformation of the first signal substrate 601, it is more preferable that the surface temperature of the resin-containing coating is in the range of 40° C. to 100° C.

Incidentally, the surface temperature is measured using a noncontact radiation thermometer.

In this manner, by heating the applied resin-containing coating so that its surface temperature is raised to a predetermined temperature, a resin-containing coating layer 105′ with a uniform thickness can be formed speedily on the first information recording layer 602 (see FIG. 3E).

In the method for manufacturing a multilayer information recording medium according to the present embodiment, the resin-containing coating may be heated with hot air in the middle of applying the resin-containing coating. Also, the applied resin-containing coating may be heated with a hot air. This is because the combination of heating and blowing an air makes it possible to smooth out the surface of the resin-containing coating more efficiently and effectively and suppress the entry of large air bubbles. It is preferable that the resin-containing coating is heated with the hot air so that its surface temperature rises to 30° C. to 100° C.

For allowing an excellent leveling of the applied resin-containing coating, the resin-containing coating may contain a surfactant. The surfactant preferably is, for example, an additive based on modified silicone or the like.

When applying the resin-containing coating, it is necessary to reduce bubbles in the resin-containing coating. To address this issue, there are three principal methods, which will be described below.

The first method is to allow the resin-containing coating to stand for a predetermined period after applying the resin-containing coating and before transferring. In other words, this method can remove air bubbles at the same time with the above-described leveling. The period for which the coating is allowed to stand is about one to five minutes, though it becomes longer with an increase in the viscosity of the resin-containing coating.

The second method is to mix a defoaming agent into the resin-containing coating. The defoaming agent is not particularly limited but can be, for example, a silicone-based defoaming agent or a non-silicone-based defoaming agent. In particular, the non-silicone-based defoaming agent is preferable in view of ensuring of the light transmittance of the resin layer. The non-silicone-based defoaming agent is not particularly limited but can be, for example, 2-ethylhexanol, a polypropylene derivative, an oleic acid or the like.

The third method is to use a resin-containing coating from which bubbles are removed in advance. The bubbles can be removed in a container such as a metallic drum container decompressed by a rotary pump or the like.

Although the effectiveness of these methods depends on the kind, viscosity, etc. of the resin contained in the resin-containing coating, the combination of these methods makes it possible to reduce the bubbles in the resin-containing coating considerably.

FIGS. 4A to 4D are sectional views showing an example of a method for transferring a signal to the resin-containing coating in the method for manufacturing a multilayer information recording medium according to the present embodiment. The first signal substrate 601 having one principal surface provided with the first information recording layer 602 and the resin-containing coating layer 105′ in this order is placed in a decompression chamber 701. The first signal substrate 601 is fixed at a predetermined position by passing a center boss 706 through a center hole 611 formed at the center of the first signal substrate 601. At the same time, a signal transfer substrate 702 also is placed in the decompression chamber 701. It is preferable that the signal transfer substrate 702 contains, for example, polyolefin, which has an excellent peelability from the ultraviolet curable resin. Since polyolefin has an excellent formability, it also is preferred as a material for the signal transfer substrate 702 in that the uneven information surface can be formed easily.

When the average thickness of the first signal substrate 601 is, for example, 1.1 mm, that of the signal transfer substrate 702 preferably is set to 0.6 mm, for example. The use of the signal transfer substrate 702 thinner than the first signal substrate 601 makes it easy to peel off the signal transfer substrate 702 owing to the difference in rigidity caused by the difference in thickness.

Further, since polyolefin has an ultraviolet-transmitting property, the resin-containing coating is irradiated with ultraviolet light through the signal transfer substrate 702, thereby curing the ultraviolet curable resin contained in the resin-containing coating efficiently. Such polyolefin can be, for example, cycloolefin made from cyclopentadiene.

The decompression chamber 701 can be exhausted by a pressure-reducing pump 703 such as a rotary pump or a mechanical booster pump and be decompressed to a predetermined pressure within a short time. In the present embodiment, when the interior of the decompression chamber 701 reaches a degree of vacuum of equal to or lower than 100 Pa, for example, the signal transfer substrate 702 and the first signal substrate 601 are attached to each other via the resin-containing coating layer 105′ and the first information recording layer 602.

At this time, the signal transfer substrate 702 is pressed with a pressing plate 704, thereby transferring the uneven surface of the signal transfer substrate 702 serving as the information surface to the resin-containing coating layer 105′. Since the interior of the decompression chamber 701 is decompressed, the resin-containing coating layer 105′ and the signal transfer substrate 702 can be attached to each other without allowing air bubbles to enter between the resin-containing coating layer 105′ and the signal transfer substrate 702 (see FIG. 4B). Moreover, it also is possible to remove the air bubbles that have entered the resin-containing coating at the time of applying the resin-containing coating 105 onto the first signal substrate 601 through the openings of the screen. Incidentally, the pressing plate 704 may be replaced by another pressing system such as a roller.

It is preferable that the pressing with the pressing system such as the pressing plate 704 is carried out at 30 to 100 kg/cm² (2.96×10−5 to 98.1×10⁻⁵ Pa). Although the transferability improves with an increase in the pressure applied to the signal transfer substrate 702, an excessively large pressure causes the warping of the multilayer information recording medium and/or the variation in thickness of the resin layer. If the pressure is within the above-mentioned range, it is possible to transfer the signal excellently without causing the warping of the multilayer information recording medium or the variation in the resin layer thickness.

After attaching the resin-containing coating layer 105′ and the signal transfer substrate 702 to each other, it is preferable to heat the signal transfer substrate 702 by a heating system (not shown) while running a pressing system such as a roller (not shown) over the signal transfer substrate 702, for example. This is because the ultraviolet curable resin that has not been cured achieves a lower viscosity when heated, allowing easy and excellent transfer of minute shapes of grooves and pits. The pressing and heating described above can be carried out using a roller provided with a heating system, for example.

It is preferable that the surface temperature of a roller 903 is 25° C. to 100° C. An excessively high temperature causes the deterioration of a resin layer and/or the warping of the multilayer information recording medium. If the surface temperature of the roller 903 is within the above-mentioned range, it is possible to perform the excellent signal transfer without causing the deterioration of the resin layer or the warping of the multilayer information recording medium.

Next, the first signal substrate 601 and the signal transfer substrate 702 that are attached to each other are taken out from the decompression chamber 701. Subsequently, an entire surface of the resin-containing coating layer 105′ is irradiated with ultraviolet light through the signal transfer substrate 702 using an ultraviolet irradiating device 705 disposed above the signal transfer substrate 702, thereby curing the ultraviolet curable resin contained in the resin-containing coating. In this manner, the resin-containing coating layer 105′ is formed into a resin layer (see FIG. 4C).

Thereafter, the signal transfer substrate 702 is peeled off from the resin layer. At this time, it is preferable to blow compressed air between the signal transfer substrate 702 and the resin layer. In this manner, the resin layer 603 on which the information is transferred is formed (see FIG. 4D).

Next, the second information recording layer 604 is formed by sputtering or the like similarly to the first information recording layer 602. The resin layer 605 also is formed similarly to the resin layer 603. Furthermore, the third information recording layer 606, the fourth information recording layer 608 and the resin layer 607 also are formed similarly. Then, the transparent layer 609 is formed on the fourth information recording layer 608. The transparent layer 609 is formed using an ultraviolet curable resin containing as a principal component an acrylic resin that is substantially transparent to (transmits) recording/reproducing light. Similarly to the resin layer, the transparent layer 609 also is formed by applying a coating for forming the transparent layer 609 to the fourth information recording layer 608 through the openings of the screen (see FIG. 1).

The average thickness of the transparent layer 609 directly above the fourth information recording layer 608 is determined according to the thickness of the resin layers 603, 605 and 607 between the transparent layer 609 and the first information recording layer 602 so that the distance from the surface of the transparent layer 609 to the first information recording layer 602 is about 100 μm. This 100 μm is a correctable limit of spherical aberration by the recording/reproducing head used in the present embodiment.

For example, in the case where the average thickness of each of the resin layers 603, 605 and 607 is 25 μm, that of the transparent layer 609 is set to 25 μm (100 μm−25 μm×3 layers). Also, in the case where the average thickness of the resin layers 603, 605 and 607 is 10 μm, that of the transparent layer 609 is set to 70 μm (100 μm−10 μm×3 layers). Incidentally, the thickness of each of the first to fourth information recording layers is incomparably smaller than that of the resin layer or the transparent layer 609 and thus is considered negligible.

In the method for manufacturing a multilayer information recording medium according to the present embodiment, all of the resin layers 603, 605 and 607, the first information recording layer 602, the second information recording layer 604, the third information recording layer 606 and the fourth information recording layer 608 are formed on the first signal substrate 601 except for the edge portions of the first signal substrate 601 (see FIG. 1). Thus, the transparent layer 609 can be formed so as to join with the outer edge portion 601a and the inner edge portion 601b of the first signal substrate 601. Consequently, the first information recording layer 602, the second information recording layer 604, the third information recording layer 606, the fourth information recording layer 608 and the resin layers 603, 605 and 607 can be surrounded by the transparent layer 609 and the first signal substrate 601. Polycarbonate has a high adhesiveness to an ultraviolet curable resin that has not been cured and a cured ultraviolet curable resin. Therefore, the use of polycarbonate as the material for the first signal substrate 601 and an ultraviolet curable resin as that for the transparent layer 609 suppresses the peeling of the resin layer and the information recording layer from each other due to moisture or the like.

In the above description, the resin-containing coating is applied onto the first signal substrate 601 except for the edge portions of the first signal substrate 601, and the first signal substrate 601 and the signal transfer substrate 702 are attached to each other via the applied resin-containing coating at a pressure lower than atmospheric pressure, thereby forming the resin layer 603 having the information surface. However, the method for manufacturing a multilayer information recording medium according to the present embodiment is not limited to this.

For example, when it is difficult to form a resin layer with a desired thickness using a resin-containing coating having a relatively low viscosity, the resin layer also may be formed as follows.

A first resin-containing coating is applied onto the signal transfer substrate 702 except for the edge portions of the signal transfer substrate 702 through openings of a first screen. On the other hand, a second resin-containing coating is applied onto the first signal substrate 601 except for the edge portions of the first signal substrate 601 through openings of a second screen. Then, the first signal substrate 601 and the signal transfer substrate 702 are attached to each other via the first and second resin-containing coatings at a pressure lower than atmospheric pressure. Thereafter, the resins contained in the first and second resin-containing coatings are cured, thereby forming the resin layer having the information surface. The first screen and the second screen each may be similar to the screen 104 described referring to FIG. 3B.

The compositions of the first resin-containing coating and the second resin-containing coating may be the same or different. For example, the content of the photocurable resin in the first resin-containing coating may be set higher than that in the second resin-containing coating. This is to improve the peelability of the resin layer from the signal transfer substrate 702 and/or improve the adhesiveness of the resin layer to the first signal substrate 601. The photocurable resin comes to have a mesh structure by light irradiation, so that a bridged structure is formed, thereby achieving an increased elasticity and a lower adhesion. Accordingly, when the content of the photocurable resin increases, the adhesion lowers to a larger degree. Thus, when the first resin-containing coating contains a more photocurable resin, the peelability of the resin layer from the signal transfer substrate 702 increases, so that the adhesiveness of the resin layer to the first signal substrate 601 improves.

As described above, since the screen printing is adopted in the present embodiment, it is possible to form each of the resin layers to have a uniform thickness at a high speed. Also, since the screen printing is adopted, an equipment installation requires less frequent maintenance than in the case of adopting spin-coating, thus reducing a manufacturing cost. Furthermore, since the resin-containing coating can be applied to the first to fourth information recording layers without bringing the screen into contact with an object to be printed in the present embodiment, it is possible to suppress damage to the first to fourth information recording layers at the time of application, thus achieving a multilayer information recording medium with an excellent quality.

Incidentally, the multilayer information recording medium illustrated in FIG. 1 includes four information recording layers, but the number of the information recording layers is not limited to four. By adjusting the thicknesses of the first signal substrate, the individual resin layers and the transparent layer, it is possible to achieve an information recording medium including two or more information recording layers.

Now, forces acting on the resin-containing coating filled in the screen 104 are gravity, a surface tension, the Coulomb force and a frictional force against the screen. The magnitude of these forces is affected by parameters such as the density, viscosity and surface tension of the resin-containing coating, a charge amount, the distance between the screen 104 and the first information recording layer 602, a surface roughness of the screen 104 and a coefficient of friction between the screen 104 and the resin-containing coating.

The relationship between a minimum distance between the screen 104 and the first information recording layer 602 and a state of the formed resin layer was studied as follows. It should be noted that the resin-containing coating had a viscosity of 2000 cps.

Table 1 shows the relationship between the minimum distance between the screen 104 and the first information recording layer 602 and the state of the formed resin layer. In Table 1, A indicates a case where the variation in thickness of the formed resin layer is within ±1 μm from a target value of the resin layer thickness, which is an average thickness of 20 μm, and B indicates a case where the above-noted variation is wider than +1 μm and within ±2 μm from the target value.

TABLE 1

Distance between screen and first
information recording portion (mm)

| | 0.3 | 0.5 | 1 | 1.5 | 2 | 2.5 | 2.8 | 3 |
|---|---|---|---|---|---|---|---|---|
| Thickness | A | A | A | A | A | A | B | B |
| accuracy | | | | | | | | |

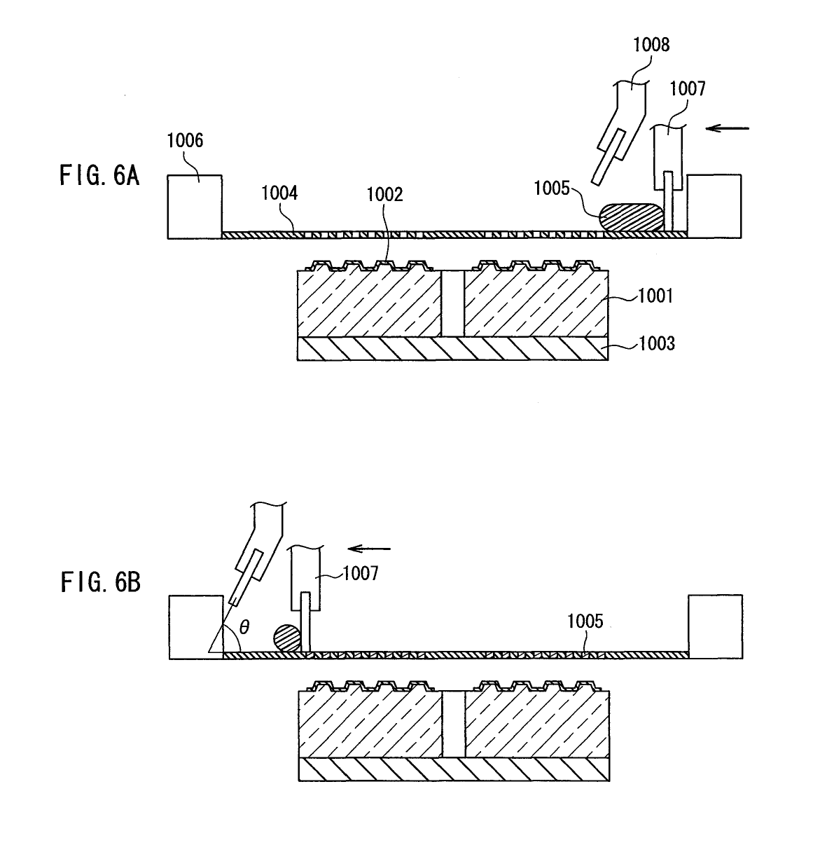

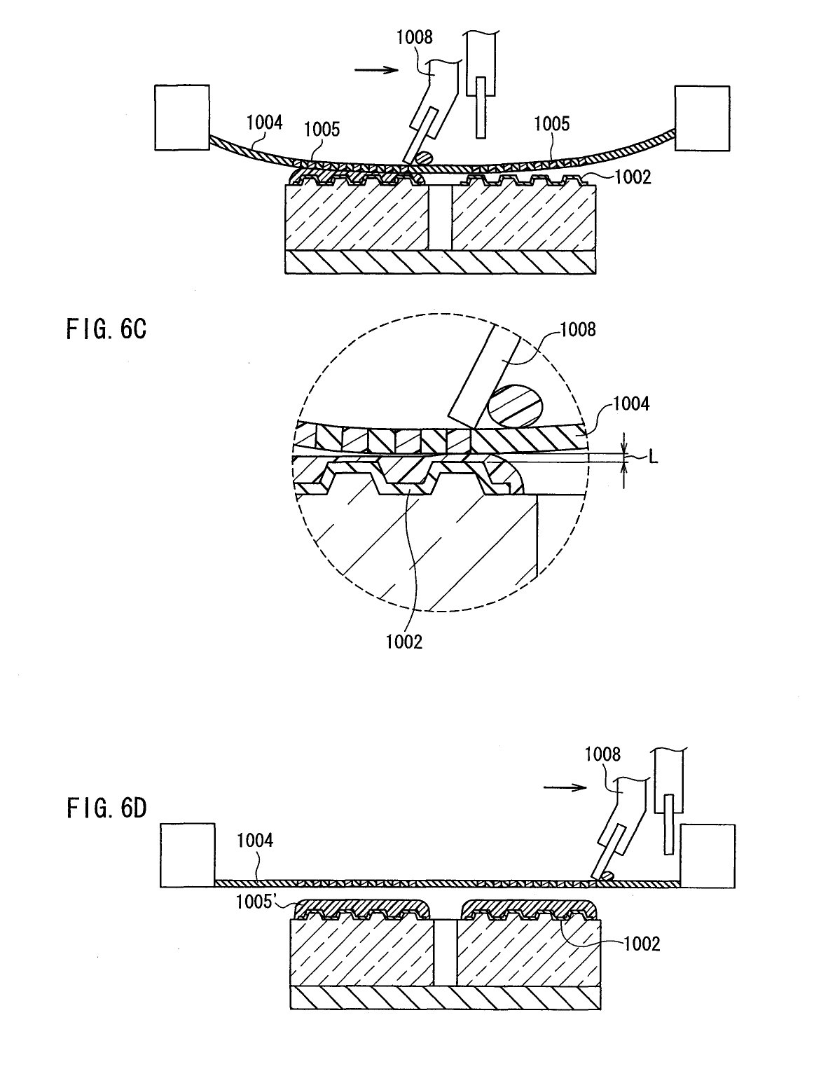

A smaller minimum distance L between the screen 4 and the first information recording layer (see FIG. 6C) is more preferable because the resin-containing coating can be made to adhere to the first information recording layer easily. However, in the present experiment, as shown in Table 1, the minimum value of the minimum distance L was 0.3 mm owing to the limit of controlling the equipment. Also, when the minimum distance L between the screen and the first information recording layer was equal to or smaller than 2.5 mm, it was possible to form the resin layer having an excellent thickness uniformity. When the above-noted minimum distance L was 2.8 mm, the resin-containing coating slightly remained inside the openings, so that the thickness uniformity of the resin layer lowered. When the above-noted minimum distance L was 3 mm, there was a problem that air bubbles entered the resin-containing coating.

When the above experiment was conducted with the resin-containing coating having a viscosity in the range of 1000 to 3000 cps, a result similar to that shown in Table 1 was obtained.

### Embodiment 2

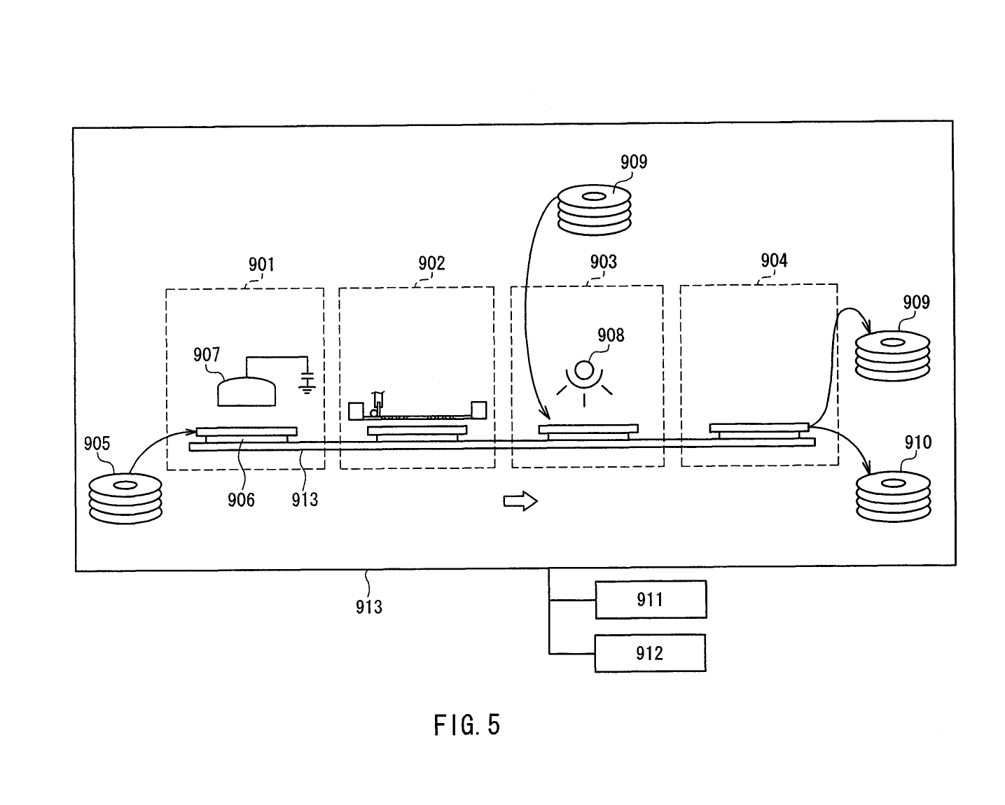

Embodiment 2 will be directed to another example of the method for manufacturing a multilayer information recording layer according to the present invention. FIG. 5 is a schematic view for describing the method for manufacturing a multilayer information recording layer according to the present embodiment. In FIG. 5, numeral 913 denotes a production apparatus, numeral 901 denotes a disk charging portion therein, numeral 902 denotes a resin printing portion, numeral 903 denotes an attaching portion, and numeral 904 denotes a peeling portion for peeling a signal transfer substrate.

As shown in FIG. 5, first, a first signal substrate 905 whose one principal surface is provided with a first information recording layer serving as an object to be printed is conveyed on a table 906 (a conveyor apparatus is not shown). The first signal substrate 905 is held to the table 906 by a suction system such as vacuum. Next, similarly to Embodiment 1, a surface of the first information recording layer is charged electrically using a corona charger 907. Then, the first signal substrate 905 provided with the electrically-charged first information recording layer is conveyed to the resin printing portion 902. The first signal substrate 905 is conveyed by a conveyor portion 913 in a direction indicated by an arrow in the figure. In the resin printing portion 902, a resin-containing coating is printed onto the first information recording layer. The details will be described with reference to FIGS. 6A to 6D.

In FIGS. 6A to 6D, numeral 1001 denotes a first signal substrate, numeral 1003 denotes a table, numeral 1002 denotes an electrically-charged first information recording layer, numeral 1004 denotes a screen, numeral 1005 denotes a resin-containing coating, numeral 1006 denotes a screen frame, numeral 1007 denotes a scraper, and numeral 1008 denotes a squeegee.

First, as shown in FIG. 6A, the electrically-charged first information recording layer 1002 is conveyed to a position below the screen 1004.

Next, as shown in FIG. 6B, by moving the scraper 107 in a direction indicated by an arrow, the resin-containing coating 1005 is filled in openings of the screen 1004.

Then, as shown in FIG. 6C, the squeegee 1008 is moved in a direction indicated by an arrow in the figure while pressing the screen 1004 with the squeegee 1008. The squeegee 1008 can be formed of a material such as a silicone rubber, polyurethane or stainless steel, and it was formed of polyurethane in the present embodiment. Since the amount of bubbles contained in the resin-containing coating and the application amount of the resin-containing coating vary depending on an angle θ (see FIG. 6B) and the material of the squeegee 1008, it is necessary to select the angle θ (see FIG. 6B) and the material of the squeegee 1008 according to the viscosity of the resin. In the present embodiment, the angle θ between the squeegee 1008 and the screen 1004 is set to 60°, for example. The pressure applied by the squeegee 1008 is adjusted so that the screen 1004 does not contact the first information recording layer 1002, as shown in the enlarged view. When the screen 1004 is brought closer to the first information recording layer 1002, a charge amount on the surface of the resin-containing coating 1005 filled in the openings of the screen 1004 increases. Accordingly, even when the screen 1004 does not contact the first information recording layer 1002, the resin-containing coating filled in the openings of the screen 1004 is pressed at a certain pressure toward the first information recording layer 1002, whereby the pressed resin-containing coating is applied to the first information recording layer 1002. The applied resin-containing coating adheres to the first information recording layer 1002 by a surface tension.

As described above, by moving the squeegee 1008 rightward in FIG. 6D, the resin-containing coating can be applied onto the first information recording layer 1002. The present embodiment uses the squeegee 1008 in order to bring the screen 1004 closer to the first information recording layer 1002. The use of the squeegee 1008 has an advantage in that the distance between the first information recording layer 1002 and the screen 1004 can be controlled by the pressure applied by the squeegee 1008. When the pressure is applied by the squeegee 1008 many times, the elastic modulus of the screen 1004 varies. However, by controlling the pressure applied by the squeegee 1008 according to the variation in the elastic modulus, it is possible to extend the lifetime of the screen 1004.

After a resin-containing coating layer 1005′ is formed on the first information recording layer 1002 in this manner, an information surface of a signal transfer substrate 909 is transferred to the resin-containing coating layer, and the resin-containing coating layer is cured by light irradiation using a light irradiator 908, thus forming a resin layer, in the attaching portion 903 as shown in FIG. 5. Then, in the peeling portion 904, the signal transfer substrate 909 is peeled off from the resin layer. The information transfer using the signal transfer substrate 909 and the peeling of the signal transfer substrate 909 are carried out similarly to Embodiment 1. Incidentally, in FIG. 5, numeral 910 denotes a substrate to which the information surface has been transferred using the signal transfer substrate.

A series of processings by the disk charging portion 901, the resin printing portion 902, the attaching portion 903 and the peeling portion 904 is carried out while keeping the entire apparatus 913 in a decompressed atmosphere using a pressure-reducing pump 911. In FIG. 5, numeral 912 denotes a pressure detection device. The pressure detection device 912 is connected to a pressure controlling device (not shown) in order to make it possible to keep the pressure inside the apparatus 913 constant.

In the example illustrated in FIG. 5, the first signal substrate 905 provided with the first information recording layer, the signal transfer substrate 909 peeled off from the resin layer and the substrate 910 are stocked inside the apparatus 913. However, in the case where the apparatus 913 includes a load lock mechanism and a plurality of chambers, the first signal substrate 905, the signal transfer substrate 909 or the substrate 910 can be supplied or taken out from a chamber different from the chamber in which the individual portions including the disk charging portion 901 are arranged.

In the present embodiment, the electrical charging, the application, transferring and curing of the resin-containing coating and the peeling of the signal transfer substrate are all carried out in the decompressed atmosphere. Therefore, it is possible to reduce contamination of the information recording medium, bubbles in the resin layer and the entry of air bubbles into the resin-containing coating during printing.

In Embodiments 1 and 2, a predetermined information recording layer is charged electrically. However, the resin-containing coating filled in the openings of the screen may be charged electrically, instead. In this case, the screen also is charged electrically. Also, a predetermined information recording layer and the resin-containing coating filled in the openings of the screen may be charged electrically so that they have opposite electric charges.

In Embodiment 1, all of the first to fourth information recording layers have a structure including the reflecting film 503, the first dielectric film 504, the recording film 505 and the second dielectric film 506 in this order from the side of the first signal substrate (see FIG. 2). However, in the present invention, the information recording layers are not limited to this structure. In the case where the multilayer information recording medium is a write once-type multilayer information recording medium, it is appropriate that each of the information recording layers includes at least a recording film. At least one of the remaining films may be omitted, or any film other than these films may be included.

### INDUSTRIAL APPLICABILITY

With the multilayer information recording medium and the method for manufacturing the same according to the present invention, it is possible to provide a multilayer information recording medium with respect to which information is reproduced and/or recorded excellently and that achieves all excellent production efficiency, and a method for manufacturing the same. The present invention is applicable not only to a disc-shaped Blu-ray Disc having a center hole but also to a memory card, a CD, a DVD, a hologram memory, etc.

1. A method for manufacturing a multilayer information recording medium comprising at least two information recording layers and a resin layer disposed between the information recording layers that are adjacent to each other, the method comprising:
a first process of filling a resin-containing coating in openings of a screen, electrically charging one of the resin-containing coating filled in the openings of the screen and a predetermined information recording layer using a charging apparatus, followed by applying the resin-containing coating filled in the openings of the screen to the predetermined information recording layer without allowing the screen and the predetermined information recording layer to contact each other, and curing a resin contained in the applied resin-containing coating so as to form the resin layer; and
a second process of forming another information recording layer on the resin layer.

2. The method for manufacturing a multilayer information recording medium according to claim 1, wherein a corona charger is used as the charging apparatus.

3. The method for manufacturing a multilayer information recording medium according to claim 1, wherein when applying the resin-containing coating to the predetermined information recording layer, a sliding member is slid on the screen so as to press the resin-containing coating filled in the openings of the screen toward the predetermined information recording layer.

4. The method for manufacturing a multilayer information recording medium according to claim 1, wherein the resin-containing coating is applied to the predetermined information recording layer, while making the screen and the predetermined information recording layer face each other such that a minimum distance between the screen and the predetermined information recording layer is equal to or smaller than 2.5 mm.

5. The method for manufacturing a multilayer information recording medium according to claim 1, wherein the resin-containing coating is applied to the predetermined information recording layer at a pressure lower than atmospheric pressure.

6. The method for manufacturing a multilayer information recording medium according to claim 1, wherein the resin-containing coating comprises a photocurable resin.

7. The method for manufacturing a multilayer information recording medium according to claim 6, wherein the photocurable resin comprises an ultraviolet curable resin.

8. The method for manufacturing a multilayer information recording medium according to claim 1, wherein the resin-containing coating comprises a surfactant.

9. The method for manufacturing a multilayer information recording medium according to claim 1, wherein the resin-containing coating comprises a defoaming agent.

10. The method for manufacturing a multilayer information recording medium according to claim 1, wherein in the first process,
a resin-containing coating layer that is formed by applying the resin-containing coating and is located on the predetermined information recording layer and a signal transfer substrate having an uneven surface as an information surface are attached to each other such that the information surface faces the resin-containing coating,
the resin contained in the resin-containing coating layer is cured so as to form the resin-containing coating layer into the resin layer, and
the signal transfer substrate is peeled off from the resin layer.

11. The method for manufacturing a multilayer information recording medium according to claim 10, wherein the resin-containing coating layer and the signal transfer substrate are attached to each other at a pressure lower than atmospheric pressure.

12. The method for manufacturing a multilayer information recording medium according to claim 10, wherein the first process is carried out at a pressure lower than atmospheric pressure.

13. The method for manufacturing a multilayer information recording medium according to claim 10, wherein the signal transfer substrate comprises a polyolefin resin.

14. The method for manufacturing a multilayer information recording medium according to claim 10, wherein the resin-containing coating layer and the signal transfer substrate are attached to each other after a predetermined period has elapsed since the resin-containing coating is applied.

15. A multilayer recording medium manufactured by the method for manufacturing a multilayer information recording medium according to claim 1.
